(19) United States
(12) Patent Application Publication
(10) Pub. No.: US 2026/0136881 A1
(43) Pub. Date: May 14, 2026

(54) VACUUM PROCESSING APPARATUS AND METHOD OF CONTROLLING VACUUM PROCESSING APPARATUS

(71) Applicant: TOKYO ELECTRON LIMITED, Tokyo (JP)

(72) Inventor: Seiji ISHIBASHI, Nirasaki City (JP)

(21) Appl. No.: 19/443,354

(22) Filed: Jan. 8, 2026

Related U.S. Application Data
(62) Division of application No. 16/580,232, filed on Sep. 24, 2019.

(30) Foreign Application Priority Data
Sep. 25, 2018 (JP) 2018179207

(51) Int. Cl. H10P 72/10; H10P 72/00; H10P 72/30

(52) U.S. Cl. CPC H10P 72/1926; H10P 72/0604; H10P 72/3218

(57) ABSTRACT

A vacuum processing apparatus for performing a predetermined process on a workpiece in a depressurized state, including: a processing module including a vacuum processing chamber whose interior is depressurized and in which the process is performed on the workpiece; a vacuum transfer module including a vacuum transfer chamber whose interior is maintained in a depressurized state; a gas supply mechanism for supplying the gas for preventing at least oxidation into the vacuum transfer chamber; and a controller for controlling the gas supply mechanism to supply the gas into the vacuum transfer chamber in an idle state in which the process is not performed on the workpiece in the vacuum processing apparatus such that a first oxygen concentration in the vacuum transfer chamber in the idle state is adjusted to be lower than a second oxygen concentration the vacuum transfer chamber in a vacuum state.

### CROSS-REFERENCE TO RELATED APPLICATION

This application is based upon and claims the benefit of priority from Japanese Patent Application No. 2018-179207, filed on Sep. 25, 2018, the entire contents of which are incorporated herein by reference.

### TECHNICAL FIELD

The present disclosure relates to a vacuum processing apparatus and a method of controlling the vacuum processing apparatus.

### BACKGROUND

Patent Document 1 discloses a vacuum processing apparatus configured to suppress the oxidation throughout a target surface to be processed of a substrate which has been subjected to a film forming process in a film forming module, when the substrate is transferred in a vacuum transfer chamber provided between a vacuum processing chamber constituting the film forming module and a load-lock chamber. The vacuum processing apparatus includes an inert gas source provided in the vacuum transfer chamber. The inert gas source supplies an inert gas toward the target surface of the substrate along a transfer area in which the substrate subjected to the film forming process is transferred, over the entire transfer area. In such a configuration, the substrate is transferred in a state where the target surface of the substrate is exposed to the inert gas. This suppresses the adhesion of moisture to the entire target surface, which suppresses the oxidation of the entire target surface.

### PRIOR ART DOCUMENT

### Patent Documents

Patent Document 1: Japanese Patent Laid-Open Publication No. 2016-004834

### SUMMARY

According to an embodiment of the present disclosure, there is provided a vacuum processing apparatus configured to perform a predetermined process on a workpiece in a depressurized state, including: a processing module including a vacuum processing chamber whose interior is depressurized and in which the predetermined process is performed on the workpiece; a vacuum transfer module connected to the vacuum processing chamber through a gate valve and comprising a vacuum transfer chamber whose interior is maintained in a depressurized state, the vacuum transfer chamber comprising a transfer mechanism configured to transfer the workpiece between the vacuum processing chamber and the vacuum transfer chamber; a gas supply mechanism configured to supply the predetermined gas for preventing at least oxidation into the vacuum transfer chamber; and a controller configured to control the gas supply mechanism, wherein the controller controls the gas supply mechanism to supply the predetermined gas into the vacuum transfer chamber in an idle state in which the predetermined process is not performed on the workpiece in the vacuum processing apparatus such that a first oxygen concentration in the vacuum transfer chamber in the idle state is adjusted to be lower than a second oxygen concentration the vacuum transfer chamber in a vacuum state.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view representing a relationship between an elapsed time period after a vacuum transfer chamber is switched to be in a vacuum state and an internal pressure and oxygen concentration in the vacuum transfer chamber.

FIG. 2 is a view representing, when the state of the vacuum transfer chamber is switched from an idle state in which the vacuum transfer chamber is in the vacuum state to an operation state by restarting the supply of a nitrogen gas, a relationship between an elapsed time period from the restarting of the supply of the nitrogen gas, and an internal pressure and oxygen concentration in the vacuum transfer chamber.

FIG. 3 is a plan view illustrating a schematic configuration of a vacuum processing apparatus according to a first embodiment.

FIG. 4 is a view for explaining an outline of a mechanism for controlling an internal atmosphere of the vacuum transfer chamber.

FIG. 5 is a view representing a relationship between a set pressure and a flow rate of a nitrogen gas inside the vacuum transfer chamber.

FIG. 6 is a view representing a relationship between a set pressure inside a vacuum transfer chamber and a concentration of oxygen inside the vacuum transfer chamber.

FIG. 7 is a view schematically illustrating an exemplary configuration of a vacuum transfer chamber according to a modification of the first embodiment.

FIG. 8 is an explanatory view illustrating a schematic configuration of a vacuum processing apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the process of manufacturing a semiconductor device, predetermined processes such as a film forming process and an etching process are performed on a workpiece such as a semiconductor wafer (hereinafter, referred to as a “wafer”) in a depressurized state. A vacuum processing apparatus for performing such processes includes a vacuum processing chamber whose interior is depressurized and in which the predetermined processes are performed, and a vacuum transfer chamber whose interior is maintained in a depressurized state. The vacuum transfer chamber includes a transfer mechanism configured to transfer the workpiece between the vacuum transfer chamber and the vacuum processing chamber.

In the vacuum processing apparatus disclosed in Patent Document 1, the inert gas source is provided in the vacuum transfer chamber to supply the inert gas toward the target surface of the substrate along the transfer area in which the substrate subjected to the film forming process is transferred, over the entire transfer area. This configuration prevents the target surface of the wafer, which has been subjected to the film forming process at a high temperature, from being oxidized by a trace amount of moisture existing in the vacuum transfer chamber when the substrate is transferred after the film forming process.

For the purpose of preventing a film from being formed on a transfer arm that is provided in the vacuum transfer chamber and constitutes a transfer mechanism of the wafer, and preventing the transfer arm from corroding, the vacuum processing apparatus supplies a nitrogen gas or the like into the vacuum transfer chamber when a processing is performed on the wafer. Thus, an internal pressure of the vacuum transfer chamber is adjusted such that the internal pressure of the vacuum transfer chamber is positive against the vacuum processing chamber.

In the vacuum processing apparatus, there is an idle state in which no process is performed on a wafer. In this idle state, conventionally, although evacuation for reducing the internal pressure of the vacuum transfer chamber of the vacuum processing apparatus is performed, the supply of gas into the vacuum transfer chamber is stopped for the purpose of cost reduction and the like. That is to say, in the idle state, the vacuum transfer chamber is in a vacuum state (the maximum level of vacuum). Even if the vacuum transfer chamber is in the vacuum state in the idle state as described above, there is no particular problem in terms of the oxidation of the target surface of the wafer.

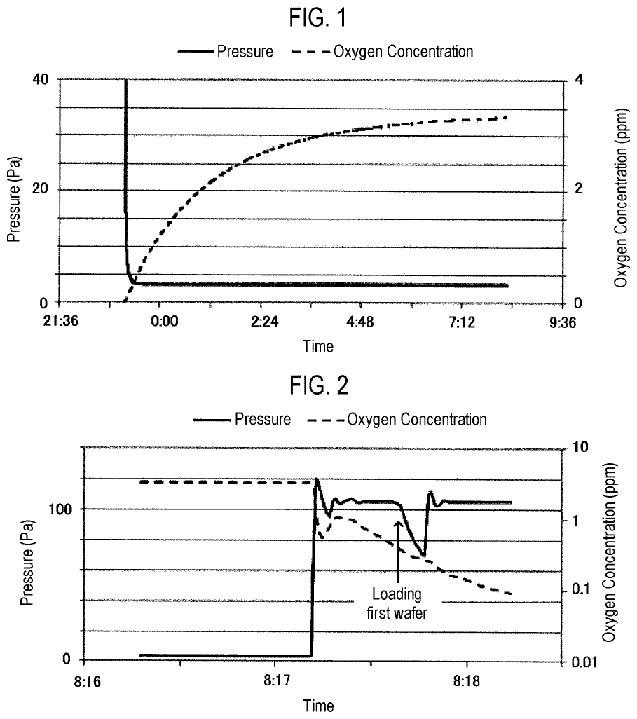

However, the semiconductor device is becoming more miniaturized, and even slight oxidation which has not been a problem in the past may affect the electrical characteristic of the semiconductor device. Through intensive investigation, the present inventors have found the points represented in FIGS. 1 and 2.

FIG. 1 is a view representing a relationship between an elapsed time period after the supply of the nitrogen gas into the vacuum transfer chamber is stopped, namely after the vacuum transfer chamber is switched to be in a vacuum state, and an internal pressure and concentration of oxygen in the vacuum transfer chamber.

FIG. 2 is a view representing, when the state of the vacuum transfer chamber is switched from an idle state in which the vacuum transfer chamber is in the vacuum state to an operation state by restarting the supply of a nitrogen gas, a relationship between an elapsed time period from the restarting of the supply of the nitrogen gas, and an internal pressure and oxygen concentration in the vacuum transfer chamber.

In each of FIGS. 1 and 2, the horizontal axis represents a time, and the vertical axis represents an internal pressure of a vacuum transfer chamber and a concentration of oxygen in the vacuum transfer chamber. In addition, in a test for obtaining the result of FIG. 2, a pressure for supplying the nitrogen gas into the vacuum transfer chamber was controlled such that an internal pressure of the vacuum transfer chamber becomes 106 Pa, which is a positive pressure against the vacuum processing chamber in an operation state in which the processing is performed on the wafer. Then, after the internal pressure of the vacuum transfer chamber is stabilized at 106 Pa, the wafer waiting in a load-lock chamber was transferred into the vacuum processing chamber via the vacuum transfer chamber. The wafer was subjected to the processing in the vacuum processing chamber, and then was returned from the vacuum processing chamber to the vacuum transfer chamber.

As represented in FIG. 1, as the time goes from the time (around 23 o'clock) at which the supply of the nitrogen gas is ceased, the concentration of oxygen in the vacuum transfer chamber was increased. The oxygen concentration was continuously increased even after the vacuum transfer chamber was in the vacuum state. In the example of FIG. 1, when about 9 hours elapsed after stopping the supply of the nitrogen gas and the internal pressure of the vacuum transfer chamber was 3.2 Pa, the oxygen concentration was increased up to 3.4 ppm.

As shown in FIG. 2, even if the idle state is returned to the operation state by restarting the supply of the nitrogen gas and the internal pressure of the vacuum transfer chamber is set to a predetermined pressure (106 Pa), the oxygen concentration in the vacuum transfer chamber did not fall completely right after the idle state is returned to the operation state. Although not shown, in particular, at the time of completing a predetermined process such as a film forming process on a first wafer after returning from the idle state to the operation state and unloading the wafer from the vacuum processing chamber to the vacuum transfer chamber, the oxygen concentration in the vacuum transfer chamber did not fall completely. As described above, when the oxygen concentration in the vacuum transfer chamber increases in the idle state, it takes time to return to the original oxygen concentration. The temperature of the wafer may become 400 degrees C or higher at the time of returning the wafer from the vacuum processing chamber to the vacuum transfer chamber. When the oxygen concentration in the vacuum transfer chamber is high at that time, the risk of deterioration of the target surface of the wafer increases due to oxidation. Patent Document 1 does not disclose this point.

A technique according to the present disclosure suppresses a workpiece from being oxidized just after the state of the vacuum processing apparatus is switched from the idle state to the operation state.

Hereinafter, a substrate processing apparatus and an inspection method according to the present embodiment will be described with reference to the drawings. In this specification and the accompanying drawings, elements having substantially the same functional configurations will be denoted by the same reference numerals and redundant explanations thereof will be omitted.

### FIRST EMBODIMENT

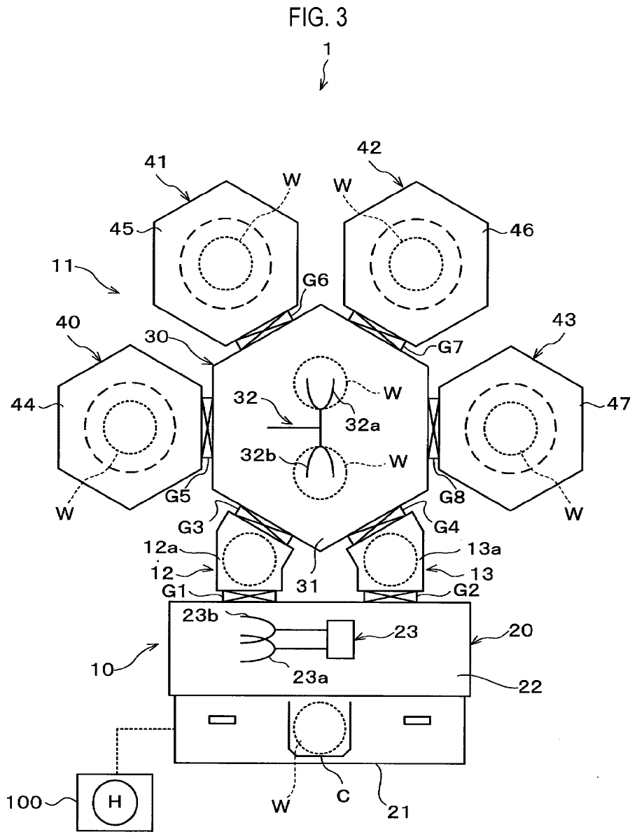

FIG. 3 is a plan view schematically illustrating the configuration of a vacuum processing apparatus 1. The vacuum processing apparatus 1 performs predetermined processes such as a film forming process, a diffusion process, an etching process and the like on the wafer W as a workpiece in a depressurized state.

The vacuum processing apparatus 1 is provided with a carrier station 10 into/from which a carrier C capable of accommodating a plurality of wafers W is transferred, and a processing station 11 including a plurality of various processing modules, each configured to perform a predetermined process on each wafer W in a depressurized state. The carrier station 10 and the processing station 11 are integrally connected with each other. The carrier station 10 and the processing station 11 are connected to each other through two load-lock modules 12 and 13.

The load-lock modules 12 and 13 include load-lock chambers 12a and 13a, respectively. The interior of each of the load-lock chambers 12a and 13a is configured to be switched between an atmospheric pressure state and a vacuum state. The load-lock modules 12 and 13 are provided to connect an atmospheric pressure transfer module 20 and a vacuum transfer module 30, which will be described later.

The carrier station 10 includes the atmospheric pressure transfer module 20 and a carrier stage 21. The carrier station 10 may be provided with an orienter (not illustrated) for adjusting the orientation of the wafer W.

The atmospheric pressure transfer module 20 includes a housing that forms an atmospheric transfer chamber 22 whose interior is maintained in an atmospheric pressure. The atmospheric transfer chamber 22 is connected to the load-lock chambers 12a and 13a of the load-lock modules 12 and 13 through respective gate valves G1 and G2. The atmospheric transfer chamber 22 includes a wafer transfer mechanism 23 configured to transfer the wafer W between the load-lock chambers 12a and 13a maintained in the atmospheric pressure and the atmospheric transfer chamber 22. The wafer transfer mechanism 23 includes two transfer arms 23a and 23b each configured to hold the wafer W in a substantially horizontal posture. The wafer transfer mechanism 23 transfers the wafer W while holding the wafer W by any of the transfer arms 23a and 23b.

The carrier stage 21 is provided on the side surface of the atmospheric pressure transfer module 20 opposite the load-lock modules 12 and 13. In the illustrated example, a plurality of (e.g., three) carriers C may be placed on the carrier stage 21. The wafers W accommodated in the carrier C placed on the carrier stage 21 are loaded into and unloaded from the atmospheric transfer chamber 22 by the transfer arms 23a and 23b of the wafer transfer mechanism 23 of the atmospheric pressure transfer module 20.

The processing station 11 includes the vacuum transfer module 30 and processing modules 40 to 43.

The vacuum transfer module 30 includes a housing that forms a vacuum transfer chamber 31 whose interior is maintained in a depressurized state (vacuum state). The housing is configured to be hermetically sealed and may be formed in a substantially polygonal shape in a plan view (a hexagonal shape in the illustrated example). The vacuum transfer chamber 31 is connected to the load-lock chambers 12a and 13a of the load-lock modules 12 and 13 through respective gate valves G3 and G4. The vacuum transfer chamber 31 includes a wafer transfer mechanism 32 configured to transfer the wafer W between vacuum processing chambers 44 to 47 (to be described later) of the processing modules 40 to 43 and the vacuum transfer chamber 31. The wafer transfer mechanism 32 includes two transfer arms 32a and 32b each configured to hold the wafer W in a substantially horizontal posture. The wafer W is transferred while being held by either of the transfer arms 32a and 32b.

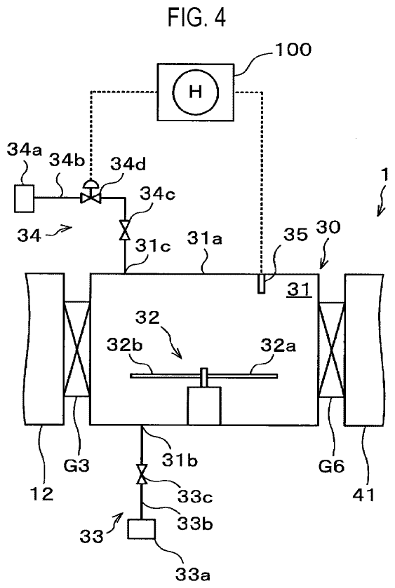

FIG. 4 is a view for explaining the outline of a mechanism for controlling an internal atmosphere of the vacuum transfer chamber 31 of the vacuum transfer module 30.

As illustrated in FIG. 4, an exhaust port 31b may be formed in the bottom surface of a housing 31a that forms the vacuum transfer chamber 31 of the vacuum transfer module 30. An exhaust mechanism 33 is connected to the exhaust port 31b. The vacuum transfer chamber 31 is exhausted by the exhaust mechanism 33 at a predetermined exhaust rate. The exhaust mechanism 33 includes a vacuum exhaust device 33a provided with a turbo molecular pump and the like, an exhaust pipe 33b connecting the vacuum exhaust device 33a and the vacuum transfer chamber 31, and an opening/closing valve 33c for opening/closing an exhaust path in the exhaust pipe 33b.

A gas supply port 31c may be formed in a ceiling surface of the housing 31a that forms the vacuum transfer chamber 31. A gas supply mechanism 34 configured to supply a nitrogen gas as a predetermined gas into the vacuum transfer chamber 31 is connected to the gas supply port 31c. The predetermined gas is used to prevent oxidation of at least the target surface of the wafer W. Further, the predetermined gas is used to adjust an internal pressure of the vacuum transfer chamber 31, prevent a film from being formed on the transfer arms 32a and 32b, and prevent the transfer arms 32a and 32b from corroding. The gas supply mechanism 34 includes a gas source 34a that stores the nitrogen gas, and a gas supply pipe 34b that connects the gas source 34a and the vacuum transfer chamber 31. The gas supply pipe 34b includes an opening/closing valve 34c for opening/closing a gas supply path in the gas supply pipe 34b, and a pressure control valve 34d for controlling a pressure of the nitrogen gas supplied from the gas source 34a into the vacuum transfer chamber 31. The pressure control valve 34d is provided at the upstream side of the opening/closing valve 34c in the gas supply pipe 34b. The control of the pressure control valve 34d, namely the control of the supply pressure of the nitrogen gas into the vacuum transfer chamber 31, is performed by a controller 100 to be described later. In the present embodiment, the nitrogen gas as an inert gas is used as a gas for oxidation prevention and pressure adjustment, but another inert gas such as an argon gas may be used.

In addition, a pressure sensor 35 as a pressure detector for detecting the internal pressure of the vacuum transfer chamber 31 is provided inside the vacuum transfer chamber 31. The detection result of the pressure sensor 35 is provided to the controller 100.

As described above, the exhaust rate of the gas by the exhaust mechanism 33 is constant. Thus, the internal pressure of the vacuum transfer chamber 31 changes depending on the supply pressure of the nitrogen gas supplied from the gas supply mechanism 34. Accordingly, by controlling the supply pressure of the nitrogen gas from the gas supply mechanism 34, the internal pressure of the vacuum transfer chamber 31 is adjusted.

The following is a description of FIG. 3. On the outside of the housing 31a (see FIG. 4) that forms the vacuum transfer chamber 31 of the vacuum transfer module 30, the processing modules 40 to 43 and the load-lock modules 12 and 13 are arranged so as to surround the above-mentioned housing 31a. The load-lock module 12, the processing modules 40 to 43, and the load-lock module 13 may be arranged in this order in a clockwise direction from the load-lock module 12 in a plan view, while facing the side surface of the housing 31a.

Each of the processing modules 40 to 43 performs a predetermined process such as a film forming process, a diffusion process, an etching process or the like on the wafer W in a depressurized state. The processing modules 40 to 43 include housings that form the vacuum processing chambers 44 to 47, respectively. The wafer W is subjected to the predetermined processes inside each of the vacuum processing chambers 44 to 47 which are maintained in the depressurized state. The vacuum processing chambers 44 to 47 are connected to the vacuum transfer chamber 31 of the vacuum transfer module 30 through respective gate valves G5 to G8 as partition valves. A module that meets the purpose of wafer processing may be arbitrarily selected from the processing modules 40 to 43.

The vacuum processing apparatus 1 configured as above is provided with the controller 100. The controller 100 may be a computer, and includes a program storage part (not illustrated). The program storage part stores a program for controlling the wafer processing in the vacuum processing apparatus 1. This program may be recorded in a non-transitory computer-readable storage medium H, and may be installed on the controller 100 from the storage medium H.

Next, the wafer processing performed using the vacuum processing apparatus 1 configured as above will be described.

First, the carrier C that accommodates the plurality of wafers W is loaded into the carrier station 10 of the vacuum processing apparatus 1 and is placed on the carrier stage 21. Subsequently, the following steps are performed to operate the vacuum processing apparatus 1 which is in an idle state, in an operation state. That is to say, the supply mode of the nitrogen gas from the gas supply mechanism 34 into the vacuum transfer chamber 31 is changed from the idle state to the operation state. The internal pressure of the vacuum transfer chamber 31 is adjusted to a set pressure in the operation state (e.g., 185 Pa). The set pressure in the operation state is positive against the pressure of each of the vacuum processing chambers 44 to 47. In addition, the supply of the gas from the gas supply mechanism 34 in the operation state is controlled such that the internal pressure of the vacuum transfer chamber 31 becomes constant at the set pressure. This control is performed by adjusting the supply pressure of the nitrogen gas through the pressure control valve 34d by the controller 100. The supply mode of the nitrogen gas in the idle state will be described later.

Upon completing the adjustment of the internal pressure of the vacuum transfer chamber, one wafer W is taken out of the carrier C by the wafer transfer mechanism 23 and is loaded into the atmospheric transfer chamber 22. Thereafter, the gate valve G1 is opened so that the interior of the atmospheric transfer chamber 22 and the interior of the load-lock chamber 12a communicate with each other. Then, the wafer W is loaded into the load-lock chamber 12a of the load-lock module 12 from the atmospheric transfer chamber 22 by the wafer transfer mechanism 23 under the atmospheric pressure.

After the wafer W is loaded into the load-lock module 12, the gate valve G1 is closed to hermetically seal the interior of the load-lock chamber 12a. The interior of the load-lock chamber 12a is depressurized. Thereafter, the gate valve G3 is opened so that the interior of the load-lock chamber 12a is in communication with the interior of the vacuum transfer chamber 31 which has been adjusted to have the set pressure in the above operation state. Then, the wafer W is unloaded from the load-lock chamber 12a by the wafer transfer mechanism 32, and is loaded into the vacuum transfer chamber 31.

After the wafer W is loaded into the vacuum transfer chamber 31, the gate valve G3 is closed. Subsequently, the gate valve G5 provided in a processing module (for example, the processing module 40) that performs a target process is opened so that the interior of the vacuum transfer chamber 31 and the vacuum processing chamber 44 communicate with each other. Then, the wafer W is unloaded from the vacuum transfer chamber 31 by the wafer transfer mechanism 32, and is loaded into the vacuum processing chamber 44.

After the wafer W is loaded into the vacuum processing chamber 44, the gate valve G5 is closed to hermetically seal the vacuum processing chamber 44. Thereafter, in the vacuum processing chamber 44, a predetermined process is performed on the wafer W in a state in which the wafer W is heated to 400 degrees C. or higher.

After the predetermined process is completed, the gate valve G5 is opened so that the interior of the vacuum processing chamber 44 and the interior of the vacuum transfer chamber 31 communicate with each other. The wafer W is returned to the vacuum transfer chamber 31 again by the wafer transfer mechanism 32. The interior of the vacuum transfer chamber 31 has been adjusted to the set pressure which is a positive against the interior of the vacuum processing chamber 44 as described above. Thus, the gas existing in the vacuum processing chamber 44 is suppressed from flowing into the vacuum transfer chamber 31.

After the wafer W is returned into the vacuum transfer chamber 31, the gate valve G5 is closed and the gate valve G4 is opened. Thus, the interior of the vacuum transfer chamber 31 and the load-lock chamber 13a of the load-lock module 13 communicate with each other. Then, the wafer W is loaded into the load-lock chamber 13a from the vacuum transfer chamber 31 by the wafer transfer mechanism 32.

After the wafer W is loaded into the load-lock chamber 13a, the gate valve G4 is closed and the interior of the load-lock chamber 13a is set to the atmospheric pressure. Then, the gate valve G2 is opened so that the interior of the load-lock chamber 13a and the interior of the atmospheric transfer chamber 22 communicate with each other. The wafer W is loaded into the atmospheric transfer chamber 22 from the load-lock chamber 13a by the wafer transfer mechanism 23 under the atmospheric pressure. After the gate valve G2 is closed, the wafer W is accommodated in the carrier C from the atmospheric transfer chamber 22 by the wafer transfer mechanism 23.

A series of processes subsequent to the above-described process of loading the wafer W from the carrier C into the atmospheric transfer chamber 22 are performed on all the wafers W stored in the respective carrier C. After the series of processes are performed on all the wafers W stored in the respective carrier C, the respective carrier C storing the plurality of wafers W is unloaded from the vacuum processing apparatus 1.

Next, the supply mode of the nitrogen gas in the vacuum processing apparatus 1, specifically, the supply mode of the nitrogen gas in the idle state in which no processing is performed on the wafer W, will be described.

When the vacuum processing apparatus 1 is in the operation state, the nitrogen gas is supplied such that the internal pressure of the vacuum transfer chamber 31 is adjusted to the set pressure which is positive against the internal pressure of each of the vacuum processing chambers 44 to 47.

The vacuum processing apparatus 1 may be in an idle state instead of the operation state. A timing at which the vacuum processing apparatus 1 is in idle state may be a time interval after the above series of processes are completed for all the wafers W stored in one carrier C (lot) and until the above series of processes are started for one wafer W stored in a subsequent carrier C.

In the conventional vacuum processing apparatus, as described above, the supply of gas into the vacuum transfer chamber was stopped in the idle state to allow the vacuum transfer chamber to be in a vacuum state.

In contrast, in the vacuum processing apparatus 1 of the present embodiment, the gas supply mechanism 34 is controlled such that the supply of the nitrogen gas from the gas supply mechanism 34 is performed even in the idle state, based on the results of the following test conducted by the present inventors. As a result, the concentration of oxygen in the vacuum transfer chamber 31 in the idle state is adjusted to be lower than that in the case in which the vacuum transfer chamber 31 is in the vacuum state.

The present inventors have conducted a test to confirm the relationship between an internal set pressure of the vacuum transfer chamber 31, a flow rate of the nitrogen gas, and a concentration of oxygen in the vacuum transfer chamber 31, by adjusting the supply pressure of the nitrogen gas from the gas supply mechanism 34 such that the internal set pressure of the vacuum transfer chamber 31 increases stepwise from the vacuum state. The flow rate of the nitrogen gas was detected using a mass flow meter provided at the downstream side of the pressure control valve 34d in the gas supply pipe 34b of the gas supply mechanism 34. The oxygen concentration was detected using an oxygen concentration sensor provided in the vicinity of the exhaust port 31b in the vacuum transfer chamber 31.

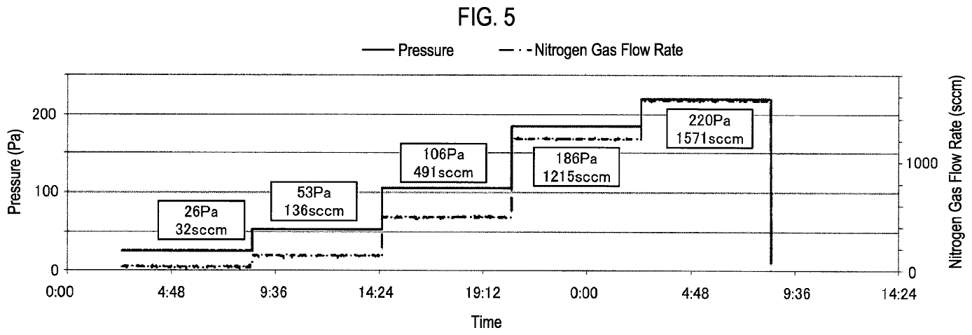

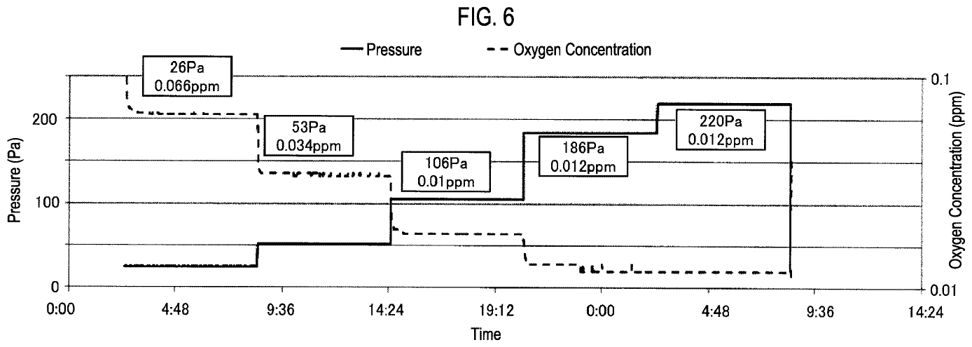

FIG. 5 is a view representing a relationship between the internal set pressure of the vacuum transfer chamber 31 and the flow rate of the nitrogen gas, which was obtained by the above-mentioned test. In FIG. 5, the horizontal axis represents time, and the vertical axis represents the internal set pressure and the flow rate of the nitrogen gas. FIG. 6 is a view representing a relationship between the internal set pressure of the vacuum transfer chamber 31 and the concentration of oxygen in the vacuum transfer chamber 31, which was obtained by the above-mentioned test. In FIG. 6, the horizontal axis represents time, and the vertical axis represents the internal set pressure and the oxygen concentration.

As represented in FIGS. 5 and 6 and FIG. 1 described above, when the internal set pressure of the vacuum transfer chamber 31 is high (in the case of 185 Pa and 220 Pa) and the nitrogen gas of a large amount is supplied, the oxygen concentration in the vacuum transfer chamber 31 was significantly reduced compared to that in the case in which the vacuum transfer chamber 31 is in the vacuum state. In addition, even when the internal set pressure of the vacuum transfer chamber 31 is low (in the case of 106 Pa, 53 Pa, and 26 Pa) and the nitrogen gas of a small amount is supplied, the oxygen concentration in the vacuum transfer chamber 31 was greatly reduced compared to that in the case in which the vacuum transfer chamber 31 is in the vacuum state. In addition, when the supply of the nitrogen gas was continuously performed, the internal pressure of the vacuum transfer chamber 31 was maintained and the oxygen concentration in the vacuum transfer chamber 31 did not increase. Thus, the oxygen concentration was maintained to meet the internal set pressure of the vacuum transfer chamber 31.

Based on the result of the test, in the present embodiment, in order to prevent the oxygen concentration in the vacuum transfer chamber 31 in the idle state from being increased as in the case in which the vacuum transfer chamber 31 is in the vacuum state, the supply of the nitrogen gas from the gas supply mechanism 34 is performed even in the idle state. In other words, in the present embodiment, the gas supply mechanism 34 is controlled such that supply of the nitrogen gas is performed even in the idle state, and the oxygen concentration in the vacuum transfer chamber 31 in the idle state is adjusted to be lower than that in the case in which the vacuum transfer chamber 31 is in the vacuum state. Specifically, the internal set pressure of the vacuum transfer chamber 31 in the idle state is set to a pressure (e.g., 26 Pa) at which the oxygen concentration in the vacuum transfer chamber 31 is lower than that in the vacuum state. In addition, based on the detection result of the pressure sensor 35, the gas supply mechanism 34 (specifically, the pressure control valve 34d) is controlled such that the internal pressure of the vacuum transfer chamber 31 is adjusted to the internal set pressure in the idle state. Thereby, the oxygen concentration in the vacuum transfer chamber 31 in the idle state is adjusted to a low value.

In the vacuum processing apparatus 1 of the present embodiment, the gas supply mechanism 34 is controlled such that the oxygen concentration in the vacuum transfer chamber 31 in the idle state becomes, for example, 0.1 ppm or lower. When the oxygen concentration in the vacuum transfer chamber 31 in the idle state is 0.1 ppm or lower, the oxygen concentration in the vacuum transfer chamber 31 is about 0.01 ppm even just after the state of the vacuum transfer chamber 31 returns the operation state from the idle state. With this configuration, in a case in which a film forming process of, for example, a metal film, is performed in any of the vacuum processing chambers 44 to 47 at the above time, and then the wafer W having a high temperature of 400 degrees C. or higher is loaded into the vacuum transfer chamber 31 from the respective vacuum processing chamber, it is possible to suppress the oxidation of the metal film formed on the wafer W. Therefore, even if the wafer W has been subjected to the film forming process just after returning the operation state from the idle state, it is possible to prevent electrical properties of the metal film formed on the wafer W, such as a film resistance, from deteriorating when the wafer W is returned to the vacuum transfer chamber 31. In addition, the oxygen concentration in the vacuum transfer chamber 31 is maintained at a low level during a time period just after returning from the idle state to the operation state and before a subsequent idle state. This prevents the electrical properties of the metal film formed on the wafer W from fluctuating in the same carrier (lot).

As represented in FIGS. 5 and 6, it can be seen from the above test conducted by the present inventors that the supply amount of the nitrogen gas and the oxygen concentration in the vacuum transfer chamber 31 are not in a proportional relationship. Specifically, for example, when the internal set pressure of the vacuum transfer chamber 31 is 185 Pa, the flow rate of the nitrogen gas needs to be 1,200 sccm or higher. At this time, the oxygen concentration in the vacuum transfer chamber 31 is 0.012 ppm. In contrast, when the internal set pressure of the vacuum transfer chamber 31 is 26 Pa, the flow rate of the nitrogen gas required at that time is 32 sccm. At this time, the oxygen concentration in the vacuum transfer chamber 31 is 0.066 ppm. That is to say, the increase in the oxygen concentration is suppressed to about 5 times with about 1/40 of the flow rate of the nitrogen gas. In addition, even when the flow rate of the nitrogen gas is about 1/40, the oxygen concentration in the vacuum transfer chamber 31 is about 1/50 of that when the vacuum transfer chamber 31 is in the vacuum state.

Based on these results, in the vacuum processing apparatus 1 of the present embodiment, the gas supply mechanism 34 may be controlled such that the internal pressure of the vacuum transfer chamber 31 becomes lower in the idle state than that in the operation state. For example, the internal set pressure of the vacuum transfer chamber 31 in the operation state may be set to 185 Pa, and the internal set pressure in the idle state may be set to 26 Pa. As a result, it is possible to suppress the increase in the oxygen concentration when switching from the operation state to the idle state while suppressing an amount of the nitrogen gas used.

According to the embodiment described above, in the vacuum processing apparatus 1, the gas supply mechanism 34 is controlled such that the supply of the nitrogen gas is performed even in the idle state, thus adjusting the oxygen concentration in the vacuum transfer chamber 31 in the idle state to be lower than that in the case in which the vacuum transfer chamber 31 is in the vacuum state. Therefore, since the oxygen concentration in the vacuum transfer chamber 31 is low even in the idle state, the oxygen concentration in the vacuum transfer chamber 31 is low even just after returning from the idle state to the operation state. Accordingly, it is possible to suppress the target surface of the wafer W from being oxidized in the vacuum transfer chamber 31 just after returning from the idle state to the operation state.

In some embodiments, the internal set pressure of the vacuum transfer chamber 31 in the idle state may not be constant during the idle state, and may be changed at a predetermined timing in the idle state. For example, the internal set pressure of the vacuum transfer chamber 31 in the idle state may be periodically changed during the idle state. More specifically, the internal set pressure of the vacuum transfer chamber 31 in the idle state may be increased whenever a predetermined period of time elapses, and the supply pressure, namely the supply amount, of the nitrogen gas may be increased. Therefore, when the internal set pressure of the vacuum transfer chamber 31 is set to be constant and the supply amount of the nitrogen gas is set to be constant in the idle state, it is possible to suppress the oxygen concentration from being increased even if the oxygen concentration in the vacuum transfer chamber 31 increases.

### Modification to First Embodiment

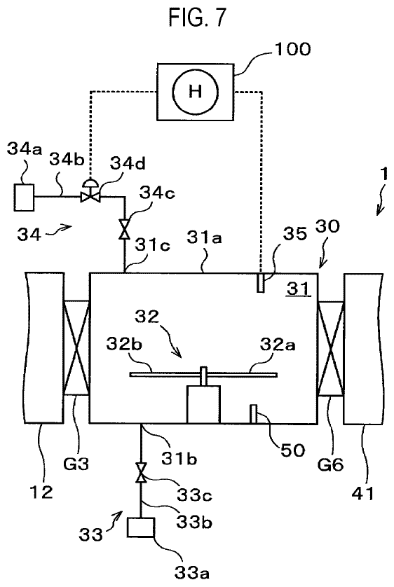

FIG. 7 is a view schematically illustrating an exemplary configuration of a vacuum transfer chamber 31 according to a modification of the first embodiment.

In addition to the respective components of the vacuum transfer chamber 31 illustrated in FIG. 4 described above, the vacuum transfer chamber 31 of FIG. 7 further includes an oxygen concentration sensor 50 provided in the vicinity of the exhaust port 31b. The oxygen concentration sensor 50 as an oxygen concentration detection part is configured to detect the configured to oxygen in the vacuum transfer chamber 31 as illustrated in FIG. 7.

In the case of using the vacuum transfer chamber 31 of FIG. 7, when changing the internal set pressure of the vacuum transfer chamber 31 in the idle state at a predetermined timing during the idle state, the predetermined timing may be determined based on the detection result of the oxygen concentration sensor 50. That is to say, the internal set pressure of the vacuum transfer chamber 31 in the idle state may be changed based on the detection result of the oxygen concentration sensor 50 during the idle state.

For example, when the detection result of the oxygen concentration sensor 50 indicates that the oxygen concentration is high, the internal set pressure of the vacuum transfer chamber 31 may be changed to a high level, so that a relatively large amount of the nitrogen gas is supplied into the vacuum transfer chamber 31. Thus, even if the oxygen concentration becomes high during the idle state, it possible to reduce the oxygen concentration.

By providing the oxygen concentration sensor 50 in the vicinity of the exhaust port 31b, it is possible to detect the oxygen concentration in the vacuum transfer chamber 31 more accurately compared to the case in which the oxygen concentration sensor 50 is provided in the vicinity of the gas supply port 31c.

### SECOND EMBODIMENT

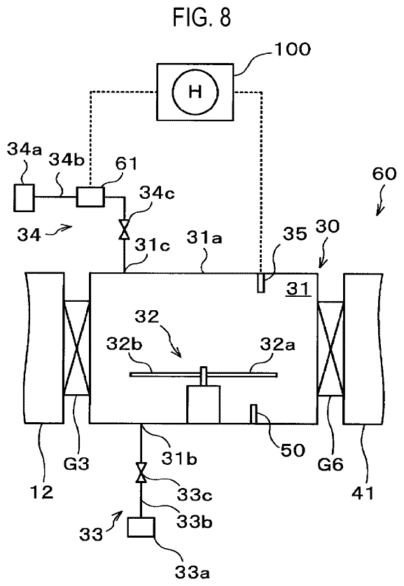

FIG. 8 is an explanatory view schematically illustrating the configuration of a vacuum processing apparatus according to a second embodiment.

In addition to the respective components of the vacuum processing apparatus 1 of FIGS. 3 and 4 described above, a vacuum processing apparatus 60 of the present embodiment illustrated in FIG. 8 further includes the oxygen concentration sensor 50 provided in the vicinity of the exhaust port 31b as an oxygen concentration detection part, like that illustrated in FIG. 7. Further, the vacuum processing apparatus 60 of the present embodiment includes a mass flow controller 61 as a flow rate controller provided in the gas supply pipe 34b, instead of the pressure control valve 34d of the vacuum processing apparatus 1 of the first embodiment.

In the first embodiment, when the oxygen concentration in the vacuum transfer chamber 31 in the idle state is adjusted to a value lower than that in the vacuum state, the internal set pressure of the vacuum transfer chamber 31 corresponding to a target oxygen concentration is set. In the idle state, in order to adjust the internal pressure of the vacuum transfer chamber 31 to the internal set pressure, the pressure control valve 34d is controlled based on the detection result of the pressure sensor 35 so that the pressure of supplying the nitrogen gas into the vacuum transfer chamber 31 is controlled.

In contrast, in the vacuum processing apparatus 60 of the present embodiment, a target oxygen concentration in the vacuum transfer chamber 31 is set when adjusting the oxygen concentration in the vacuum transfer chamber 31 in the idle state to a value lower than that in the vacuum state. In the idle state, in order to set the oxygen concentration in the vacuum transfer chamber 31 to the target oxygen concentration, the mass flow controller 61 is controlled based on the detection result of the oxygen concentration sensor 50 so that the supply flow rate of the nitrogen gas into the vacuum transfer chamber 31 is controlled.

Even in the present embodiment, the oxygen concentration in the vacuum transfer chamber 31 in the idle state becomes lower than that in the case in which the vacuum transfer chamber 31 is in the vacuum state. Accordingly, it is possible to suppress the oxidation of the target surface of the wafer W in the vacuum transfer chamber 31 just after returning from the idle state to the operation state.

Even in the present embodiment, the internal pressure of the vacuum transfer chamber 31 is adjusted to the internal set pressure by the supply of the nitrogen gas from the gas supply mechanism 34 in the operation state.

The target oxygen concentration in the vacuum transfer chamber 31 in the idle state may be set such that the internal pressure of the vacuum transfer chamber 31 is lower in the idle state than in the operation state. That is to say, the supply flow rate of the nitrogen gas in the idle state may be lower than that in the operation state. As a result, it is possible to suppress the oxygen concentration in the vacuum transfer chamber 31 from being increased while suppressing the consumption of the nitrogen gas.

### Modification to First and Second Embodiments

In the first embodiment, the pressure control valve of the gas supply mechanism is controlled based on the detection result of the pressure sensor. In the second embodiment, the mass flow controller of the gas supply mechanism is controlled based on the detection result of the oxygen concentration sensor. Alternatively, the mass flow controller of the gas supply mechanism may be controlled based on the detection result of the pressure sensor, and the pressure control valve of the gas supply mechanism may be controlled based on the detection result of the oxygen concentration sensor.

In the test results represented in FIG. 1, as described above, when the internal pressure of the vacuum transfer chamber was 3.2 Pa, the oxygen concentration in the vacuum transfer chamber was 3.4 ppm. When the oxygen contained by 20.6% at the atmospheric pressure (1×104 Pa) is depressurized to a pressure of 3.2 Pa while the partial pressure thereof is maintained, the oxygen concentration becomes 6.6 ppm in computation. The reason why the oxygen concentration was 3.4 ppm, which is lower than 6.6 ppm in computation, may include an error in the oxygen concentration sensor, an exhaust efficiency of the exhaust pump that is caused by a difference in molecular weight and mean free path depending on gas species, a difference in transmittance on a seal surface depending on gas species, and the like.

It should be noted that the embodiments and modifications disclosed herein are exemplary in all respects and are not restrictive. The above-described embodiments may be omitted, replaced or modified in various forms without departing from the scope and spirit of the appended claims.

The following configurations also belong to the technical scope of the present disclosure.

(1) A vacuum processing apparatus configured to perform a predetermined process on a workpiece in a depressurized state, includes: a processing module including a vacuum processing chamber whose interior is depressurized and in which the predetermined process is performed on the workpiece; a vacuum transfer module connected to the vacuum processing chamber through a gate valve and comprising a vacuum transfer chamber whose interior is maintained in a depressurized state, the vacuum transfer chamber comprising a transfer mechanism configured to transfer the workpiece between the vacuum processing chamber and the vacuum transfer chamber; a gas supply mechanism configured to supply the predetermined gas for preventing at least oxidation into the vacuum transfer chamber; and a controller configured to control the gas supply mechanism, wherein the controller controls the gas supply mechanism to supply the predetermined gas into the vacuum transfer chamber in an idle state in which the predetermined process is not performed on the workpiece in the vacuum processing apparatus such that a first oxygen concentration in the vacuum transfer chamber in the idle state is adjusted to be lower than a second oxygen concentration the vacuum transfer chamber in a vacuum state.

According to Item (1), since the oxygen concentration in the vacuum transfer chamber in the idle state is low, the oxygen concentration in the vacuum transfer chamber is low even just after returning from the idle state to an operation state. Accordingly, it is possible to suppress the target surface of the workpiece from being oxidized in the vacuum transfer chamber just after returning from the idle state to the operation state.

(2) In the vacuum processing apparatus of Item 1, the controller controls the gas supply mechanism to supply the predetermined gas into the vacuum transfer chamber in the operation state in which the predetermined process is performed on the workpiece in the vacuum processing apparatus such that an internal pressure of the vacuum transfer chamber in the operation state is adjusted to be higher than an internal pressure of the vacuum processing chamber, and such that the internal pressure of the vacuum transfer chamber is lower in the idle state than in the operation state.

According to Item (2), it is possible to suppress the oxygen concentration from being increased in the idle state while suppressing consumption of the gas in the idle state.

(3) The vacuum processing apparatus of Item 1 or 2 further includes a pressure detector configured to detect the internal pressure of the vacuum transfer chamber, wherein the controller controls the gas supply mechanism based on a detection result of the pressure detector in the idle state, to adjust the first oxygen concentration in the vacuum transfer chamber in the idle state.

(4) In the vacuum processing apparatus of Item 3, the gas supply mechanism includes a pressure control valve configured to adjust a pressure for supplying the predetermined gas into the vacuum transfer chamber, and wherein the controller controls the pressure control valve based on the detection result of the pressure detector in the idle state, to adjust the first oxygen concentration in the vacuum transfer chamber in the idle state.

(5) In the vacuum processing apparatus of Item 3 or 4, an internal set pressure of the vacuum transfer chamber in the idle state is changed at a predetermined timing during the idle state.

(6) In the vacuum processing apparatus of Item 5, the internal set pressure of the vacuum transfer chamber in the idle state is periodically changed during the idle state.

(7) The vacuum processing apparatus of Claim 5 further includes an oxygen concentration detector configured to detect the first oxygen concentration in the vacuum transfer chamber, wherein the internal set pressure of the vacuum transfer chamber in the idle state is changed during the idle state based on a detection result of the oxygen concentration detector.

(8) The vacuum processing apparatus of Item 1 or 2 further includes an oxygen concentration detector configured to detect the first oxygen concentration in the vacuum transfer chamber, wherein the controller controls the gas supply mechanism based on a detection result of the oxygen concentration detector in the idle state, to adjust the first oxygen concentration in the vacuum transfer chamber in the idle state.

(9) In the vacuum processing apparatus of Item 8, the gas supply mechanism includes a flow rate controller configured to control a supply flow rate of the predetermined gas to be supplied into the vacuum transfer chamber, wherein the controller controls the flow rate controller based on a detection result of the oxygen concentration detector in the idle state, to adjust the first oxygen concentration in the vacuum transfer chamber in the idle state.

(10) In the vacuum processing apparatus of any one of Items 1 to 9, the predetermined process is performed on the workpiece in a state in which the workpiece is heated to 400 degrees C or higher in the vacuum processing chamber of the processing module.

(11) In the vacuum processing apparatus of any one of Items 1 to 10, the controller controls the gas supply mechanism such that the first oxygen concentration in the vacuum transfer chamber in the idle state is equal to or less than a set value.

(12) In the vacuum processing apparatus of Item 11, the set value is 0.1 ppm.

According to Item (12), when the oxygen concentration in the vacuum transfer chamber in the idle state is 0.1 ppm or less, it is possible to significantly reduce the oxygen concentration in the vacuum transfer chamber at a time just after returning from the idle state to the operation state. Accordingly, it is possible to reliably suppress the oxidation of the workpiece in the above time.

(13) A method of controlling a vacuum processing apparatus that performs a predetermined process on a workpiece in a depressurized state, wherein the vacuum processing apparatus includes: a processing module including a vacuum processing chamber whose interior is depressurized and in which the predetermined process is performed on the workpiece; a vacuum transfer module connected to the vacuum processing chamber through a gate valve and including a vacuum transfer chamber whose interior is maintained in a depressurized state, the vacuum transfer chamber including a transfer mechanism configured to transfer the workpiece between the vacuum processing chamber and the vacuum transfer chamber; and a gas supply mechanism configured to supply the predetermined gas for preventing at least oxidation into the vacuum transfer chamber, the method including: controlling the gas supply mechanism to supply the predetermined gas into the vacuum transfer chamber in an idle state in which the predetermined process is not performed on the workpiece in the vacuum processing apparatus such that a first oxygen concentration in the vacuum transfer chamber in the idle state is adjusted to be lower than a second oxygen concentration the vacuum transfer chamber in a vacuum state.

According to the present disclosure, it is possible to suppress a workpiece from being oxidized just after a state of a vacuum processing apparatus is switched from an idle state to an operation state.

1-13. (canceled)

14. A method of controlling a vacuum processing apparatus that performs a predetermined process on a workpiece in a depressurized state,
wherein the vacuum processing apparatus comprises:
a processing module including a vacuum processing chamber whose interior is depressurized and in which the predetermined process is performed on the workpiece;
a vacuum transfer module connected to the vacuum processing chamber through a gate valve and including a vacuum transfer chamber whose interior is maintained in a depressurized state, the vacuum transfer chamber including a transfer mechanism configured to transfer the workpiece between the vacuum processing chamber and the vacuum transfer chamber; and
a gas supply mechanism configured to supply the predetermined gas for preventing at least oxidation into the vacuum transfer chamber,
the method comprising:
controlling the gas supply mechanism to supply the predetermined gas into the vacuum transfer chamber in an idle state in which the predetermined process is not performed on the workpiece in the vacuum processing apparatus such that a first oxygen concentration in the vacuum transfer chamber in the idle state is adjusted to be lower than a second oxygen concentration in the vacuum transfer chamber in a vacuum state,
wherein an internal pressure of the vacuum transfer chamber in the idle state is equal to or more than 26 Pa and less than 185 Pa.

15. The method of claim 14, wherein, in controlling the gas supply mechanism, the gas supply mechanism is controlled to supply the predetermined gas into the vacuum transfer chamber in an operation state in which the predetermined process is performed on the workpiece in the vacuum processing apparatus such that an internal pressure of the vacuum transfer chamber in the operation state is adjusted to be higher than an internal pressure of the vacuum processing chamber, and such that the internal pressure of the vacuum transfer chamber is lower in the idle state than in the operation state.

16. The method of claim 14, wherein the vacuum processing apparatus further comprises a pressure detector configured to detect the internal pressure of the vacuum transfer chamber,
wherein, in controlling the gas supply mechanism, the gas supply mechanism is controlled to adjust the first oxygen concentration in the vacuum transfer chamber in the idle state based on a detection result of the pressure detector in the idle state.

17. The method of claim 16, wherein the gas supply mechanism comprises a pressure control valve configured to adjust a pressure for supplying the predetermined gas into the vacuum transfer chamber, and
wherein, in controlling the gas supply mechanism, the pressure control valve is controlled to adjust the first oxygen concentration in the vacuum transfer chamber in the idle state based on the detection result of the pressure detector in the idle state.

18. The method of claim 16, wherein, in controlling the gas supply mechanism, an internal set pressure of the vacuum transfer chamber in the idle state is changed at a predetermined timing during the idle state.

19. The method of claim 18, wherein, in controlling the gas supply mechanism, the internal set pressure of the vacuum transfer chamber in the idle state is periodically changed during the idle state.

20. The method of claim 18, wherein the vacuum processing apparatus further comprises an oxygen concentration detector configured to detect the first oxygen concentration in the vacuum transfer chamber,
wherein, in controlling the gas supply mechanism, the internal set pressure of the vacuum transfer chamber in the idle state is changed during the idle state based on a detection result of the oxygen concentration detector.

21. The method of claim 14, wherein the vacuum processing apparatus further comprises an oxygen concentration detector configured to detect the first oxygen concentration in the vacuum transfer chamber,
wherein, in controlling the gas supply mechanism, the gas supply mechanism is controlled to adjust the first oxygen concentration in the vacuum transfer chamber in the idle state based on a detection result of the oxygen concentration detector in the idle state.

22. The method of claim 21, wherein the gas supply mechanism comprises a flow rate controller configured to control a supply flow rate of the predetermined gas to be supplied into the vacuum transfer chamber, and
wherein, in controlling the gas supply mechanism, the flow rate controller is controlled to adjust the first oxygen concentration in the vacuum transfer chamber in the idle state based on the detection result of the oxygen concentration detector in the idle state.

23. The method of claim 14, further comprising performing the predetermined process on the workpiece in a state in which the workpiece is heated to 400 degrees C. or higher in the vacuum processing chamber of the processing module.

24. The method of claim 14, wherein, in controlling the gas supply mechanism, the gas supply mechanism is controlled such that the first oxygen concentration in the vacuum transfer chamber in the idle state is equal to or less than a set value.

25. The method of claim 24, wherein the set value is 0.1 ppm.
